(19) United States
(12) Patent Application Publication
(10) Pub. No.: US 2023/0089666 A1
(43) Pub. Date: Mar. 23, 2023

(54) IMPROVED ALIGNMENT OF SCATTEROMETER BASED PARTICLE INSPECTION SYSTEM

(71) Applicant: ASML Holding N.V., Veldhoven (NL)

(72) Inventors: Christopher Michael DOHAN, Redding, CT (US); James Hamilton WALSH, Newtown, CT (US); Roberto B. WIENER, Ridgefield, CT (US)

(73) Assignee: ASML Holding N.V., Veldhoven (NL)

(21) Appl. No.: 17/797,421

(22) PCT Filed: Jan. 21, 2021
(86) PCT No.: PCT/EP2021/051366

§ 371 Date: Aug. 3, 2022

Related U.S. Application Data
(60) Provisional application No. 62/969,261, filed on Feb. 3, 2020.

(51) Int. Cl. G01N 21/956; G03F 7/20

(52) U.S. Cl. CPC G01N 21/956; G03F 7/70516; G03F 7/70941

(57) ABSTRACT

A pattering device inspection apparatus, system and method are described. According to one aspect, an inspection method is disclosed, the method including receiving, at a multi-element detector within an inspection system, radiation scattered at a surface of an object. The method further includes measuring, with processing circuitry, an output of each element of the multi-element detector, the output corresponding to the received scattered radiation. Moreover, the method includes calibrating, with the processing circuitry, the multi-element detector by identifying an active pixel area comprising one or more elements of the multi-element detector with a measured output being above a predetermined threshold. The method also includes identifying an inactive pixel area comprising a remainder of elements of the multi-element detector. Additionally, the method includes setting the active pixel area as a default alignment setting between the multi-element detector and a light source causing the scattered radiation.

### CROSS-REFERENCE TO RELATED APPLICATIONS

This application claims priority of U.S. Provisional Patent Application No. 62/969,261, which was filed on Feb. 3, 2020, and which is incorporated herein in its entirety by reference.

### FIELD

The present disclosure relates to detection of contamination on lithographic patterning devices in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs) or other devices designed to be functional. In that instance, a patterning device, which is alternatively referred to as a mask or a reticle, may be used to generate a circuit pattern to be formed on an individual layer of the device designed to be functional. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti parallel to this direction. It is also possible to transfer the pattern from the patterning device to the substrate by imprinting the pattern onto the substrate.

Manufacturing devices, such as semiconductor devices, typically involves processing a substrate (e.g., a semiconductor wafer) using a number of fabrication processes to form various features and often multiple layers of the devices. Such layers and/or features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a pattern transfer step, such as optical and/or nanoimprint lithography using a lithographic apparatus, to provide a pattern on a substrate and typically, but optionally, involves one or more related pattern processing steps, such as resist development by a development apparatus, baking of the substrate using a bake tool, etching the pattern by an etch apparatus, etc. Further, one or more metrology processes are involved in the patterning process.

Metrology processes are used at various steps during a patterning process to monitor and/or control the process. For example, metrology processes are used to measure one or more characteristics of a substrate, such as a relative location (e.g., registration, overlay, alignment, etc.) or dimension (e.g., line width, critical dimension (CD), thickness, etc.) of features formed on the substrate during the patterning process, such that, for example, the performance of the patterning process can be determined from the one or more characteristics. If the one or more characteristics are unacceptable (e.g., out of a predetermined range for the characteristic(s)), one or more variables of the patterning process may be designed or altered, e.g., based on the measurements of the one or more characteristics, such that substrates manufactured by the patterning process have an acceptable characteristic(s).

With the advancement of lithography and other patterning process technologies, the dimensions of functional elements have continually been reduced while the amount of the functional elements, such as transistors, per device has been steadily increased over decades. In the meanwhile, the requirement of accuracy in terms of overlay, critical dimension (CD), etc. has become more and more stringent. Error, such as error in overlay, error in CD, etc., will inevitably be produced in the patterning process. For example, imaging error may be produced from optical aberration, patterning device heating, patterning device error, and/or substrate heating and can be characterized in terms of, e.g., overlay, CD, etc. Additionally or alternatively, error may be introduced in other parts of the patterning process, such as in etch, development, bake, etc. and similarly can be characterized in terms of, e.g., overlay, CD, etc. The error may cause a problem in terms of the functioning of the device, including failure of the device to function, contamination, or one or more electrical problems of the functioning device. Accordingly, it is desirable to be able to characterize one or more these errors and take steps to design, modify, control, etc. a patterning process to reduce or minimize one or more of these errors.

One such error that may be produced is contamination on a surface of the lithographic patterning device. Such contamination may include the presence of particles on the surface of the lithographic patterning device which may affect the etching of the pattern itself and/or subsequent inaccuracies in the patterning process, which may result in damaged and/or non-performing circuits.

As such, these errors can also contribute to added costs due to inefficient processing, waste, and processing delays.

### SUMMARY

Accordingly, there is a need to determine a level of contamination of a patterning device, including size and location of contaminants, and determining whether to accept the device as within a predefined tolerance, or to reject the device as being contaminated beyond the predefined tolerance.

In some embodiments, a lithographic inspection apparatus, system and method are described herein. According to some aspects, an inspection method is described including receiving, at a multi-element detector within an inspection system, radiation scattered at a surface of an object. The method further includes measuring, with processing circuitry, an output of each element of the multi-element detector, the output corresponding to the received scattered radiation. Moreover, the method further includes calibrating, with the processing circuitry, the multi-element detector by identifying an active pixel area comprising one or more elements of the multi-element detector with a measured output being above a predetermined threshold, and identifying an inactive pixel area comprising a remainder of elements of the multi-element detector, and setting the active pixel area as a default alignment setting between the multi-element detector and a light source causing the scattered radiation.

According to some aspects, the inspection method may further include receiving, at the multi-element detector, second radiation scattered at the surface of the object, and generating a detection signal based on outputs of the active pixels, the detection signal indicating a presence of a foreign particle on the surface. The inspection method may also include determining, based on an output of the inactive pixel area, a spurious signal, the spurious signal indicating scatter light, and discarding the output of the inactive pixel area.

According to some aspects, an illumination spot generated by the scattered radiation on the surface area of the multi-element detector may be smaller than a detection surface area of the multi-element detector, and the active pixel area comprises to the illumination spot.

According to some embodiments, the method may further include determining a spurious signal in response to the detection signal being received from the inactive pixel area, and classifying the spurious signal as a false positive signal. Moreover, the method may also include determining a location of the foreign particle based on measuring pixel outputs from pixels within the active pixel area, identifying one or more pixels within the active pixel area with the highest output levels, and extrapolating a location of the foreign particle based on a location of the identified one or more pixels within the active pixel area.

According to some embodiments, the method may further include performing a compensation operation by identifying a misalignment condition between the multi-element detector and the light source, and further, by reinitializing the calibration operation in response to identifying the misalignment. In this regard, the identifying may further include detecting a new plurality of elements within the active pixel area or within the inactive pixel area bordering the active pixel area that are outside of an illumination spot generated by the scattered radiation on the surface area of the multi-element detector, the new plurality of elements each generating an output above a predetermined threshold over one or more inspection operations.

According to some aspects, the method may further include setting a new active pixel area as a default alignment setting between the multi-element detector and the light source. Moreover, according to some aspects, the misalignment condition may be a drift condition in which a drift may occur (or a shift) between the optical elements, that may result in a misalignment between the illumination area and the detection area.

Further features and advantages of the disclosure, as well as the structure and operation of various embodiments of the disclosure, are described in detail below with reference to the accompanying drawings. It is noted that the disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the disclosure and to enable a person skilled in the relevant art(s) to make and use the disclosure.

FIG. 1A shows a schematic of a reflective lithographic apparatus, according to some embodiments;

FIG. 1B shows a schematic of a transmissive lithographic apparatus, according to some embodiments;

FIG. 2 shows a detailed schematic of a reflective lithographic apparatus, according to some embodiments;

FIG. 3 shows a schematic of a lithographic cell, according to some embodiments;

FIG. 4 shows a schematic of a metrology system, according to some embodiments;

FIG. 5 shows a schematic of a lithographic patterning device inspection system using laser scanning, according to some embodiments;

FIGS. 6A-6C illustrates alignment of illumination spot on a lithographic patterning device with a photodetector, according to some embodiments;

FIG. 7 illustrates a traditional spot across photodetector that requires perfect alignment;

FIG. 8 illustrates an oversized two dimensional image sensor array to improve positioning tolerances of the illumination spot, according to some embodiments;

FIG. 9 illustrates a flow diagram illustrating an example method for inspecting a surface of an object, according to some embodiments;

FIG. 10 illustrates a flow diagram illustrating an example method for calibrating an inspection detector to inspect a surface of an object, according to some embodiments;

FIG. 11 illustrates a flow diagram illustrating an example method for detecting an alignment drift, according to some embodiments;

FIG. 12 illustrates a flow diagram illustrating an example method for aligning illumination optics with detection optics, according to some embodiments;

FIG. 13 is an illustration of a detector device including an array of photodiodes, according to some embodiments;

FIG. 14 is an illustration of a combination of detectors used to detect particles on a lithographic patterning device, according to some embodiments;

FIGS. 15A-15B illustrate a combination of detectors used to detect particles on a lithographic patterning device, according to some embodiments; and

FIG. 16 illustrates an internal construction of a combination sensor, according to some embodiments.

The features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of this disclosure. The disclosed embodiment(s) merely exemplify the disclosure. The scope of the disclosure is not limited to the disclosed embodiment(s). The disclosure is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” can be used herein to indicate the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the present disclosure can be implemented in hardware, firmware, software, or any combination thereof. Embodiments of the present disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, non-transitory computer readable instructions, etc.

Before describing such embodiments in more detail, however, it is instructive to present an example environment in which embodiments of the present disclosure can be implemented.

Example Lithographic Systems

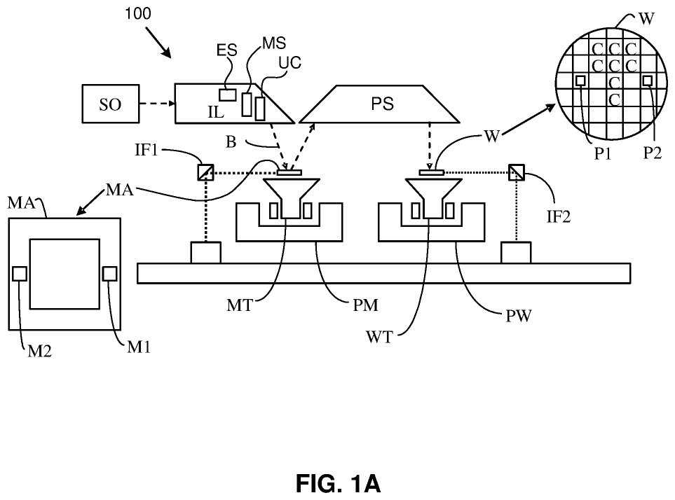

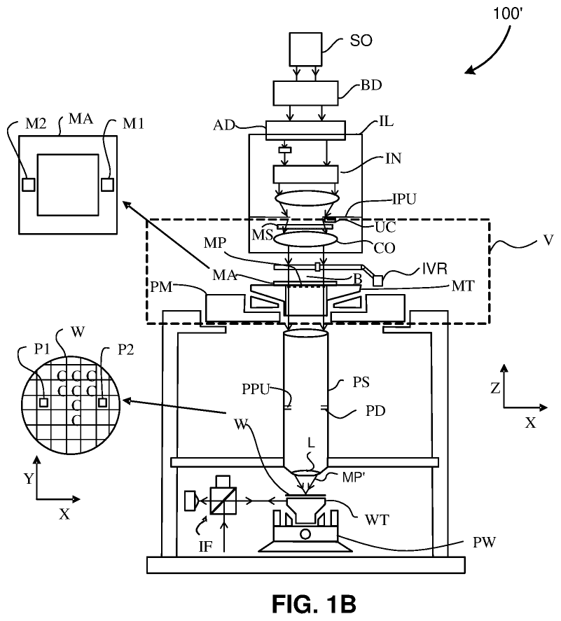

FIGS. 1A and 1B show schematics of a lithographic apparatus 100 and lithographic apparatus 100′, respectively, according to some embodiments. In some embodiments, lithographic apparatus 100 and lithographic apparatus 100′ each include the following: an illumination system (illuminator) IL configured to condition a radiation beam B (for example, deep ultra violet or extreme ultra violet (EUV) radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. As will be further described herein, other configurations of the illuminator may be implemented to for improved illumination, and compactness of design.

Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, and programmable LCD panels. Masks are well known in lithography, and include mask types such as binary, alternating phase shift, and attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′—for example when the source SO is a mercury lamp. The source SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil PPU conjugate to an illumination system pupil IPU. Portions of radiation emanate from the intensity distribution at the illumination system pupil IPU and traverse a mask pattern without being affected by diffraction at a mask pattern and create an image of the intensity distribution at the illumination system pupil IPU.

With the aid of the second positioner PW and position sensor IF (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In some embodiments, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator only or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

Lithographic apparatus 100′ may include a patterning device transfer system. An example patterning device transfer system may be a patterning device exchange apparatus (V) including, for example, in-vacuum robot IVR, mask table MT, first positioner PM and other like components for transferring and positioning a patterning device. Patterning device exchange apparatus V may be configured to transfer patterning devices between a patterning device carrying container and a processing tool (e.g. lithographic apparatus 100′).

The lithographic apparatus 100 and 100′ can be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some embodiments, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

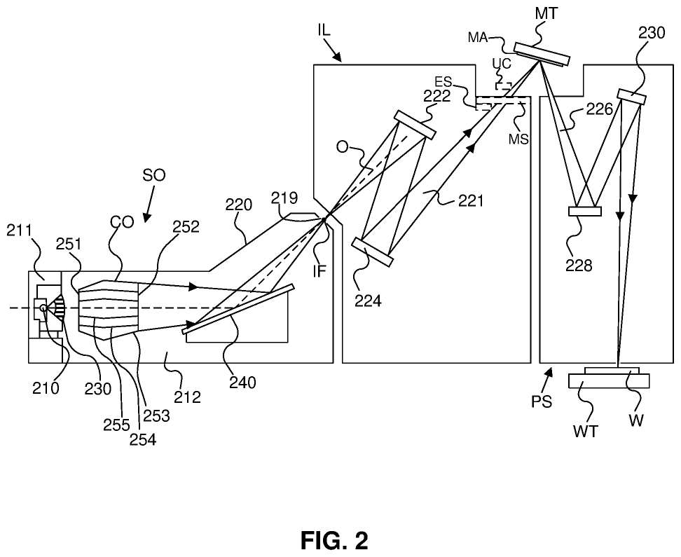

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 212 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF. The virtual source point IF is commonly referred to as the intermediate focus, and the source collector apparatus is arranged such that the intermediate focus IF is located at or near an opening 219 in the enclosing structure 220. The virtual source point IF is an image of the radiation emitting plasma 210. Grating spectral filter 240 is used in particular for suppressing infra-red (IR) radiation.

Subsequently the radiation traverses the illumination system IL, which may include a facetted field mirror device 222 and a facetted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 230 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 2.

Collector optic CO, as illustrated in FIG. 2, is depicted as a nested collector with grazing incidence reflectors 253, 254 and 255, just as an example of a collector (or collector mirror). The grazing incidence reflectors 253, 254 and 255 are disposed axially symmetric around an optical axis O and a collector optic CO of this type is preferably used in combination with a discharge produced plasma source, often called a DPP source.

Exemplary Lithographic Cell

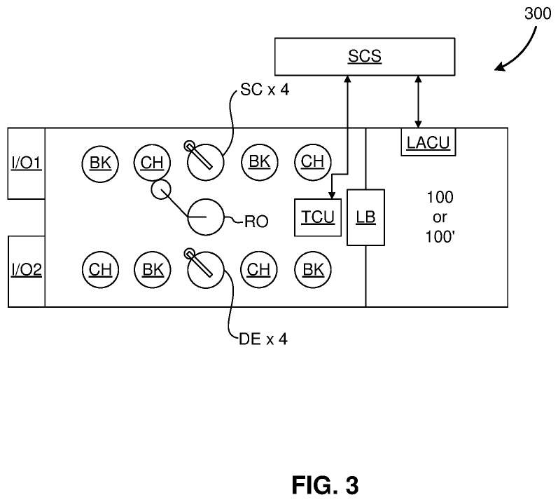

FIG. 3 shows a schematic of a lithographic cell 300, also sometimes referred to a lithocell or cluster. Lithographic apparatus 100 or 100′ may form part of lithographic cell 300. Lithographic cell 300 may also include apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

Exemplary Metrology System

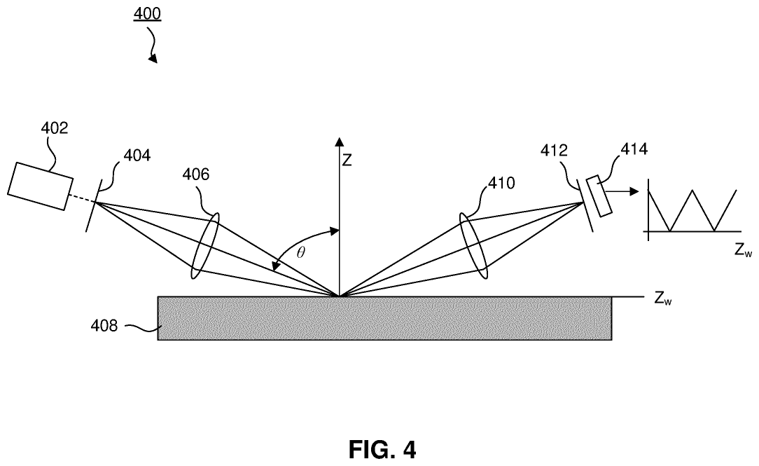

FIG. 4 shows a schematic of a metrology system 400 that can be implemented as a part of lithographic apparatus 100 or 100′, according to some embodiments. In some embodiments, metrology system 400 may be configured to measure height and height variations on a surface of substrate W. In some embodiments, metrology system 400 may be configured to detect positions of alignment marks on the substrate and to align the substrate with respect to the patterning device or other components of lithography apparatus 100 or 100′ using the detected positions of the alignment marks.

In some embodiments, metrology system 400 may include a radiation source 402, a projection grating 404, a detection grating 412, and a detector 414. Radiation source 402 may be configured to provide an electromagnetic narrow band radiation beam having one or more passbands. In some embodiments, the one or more passbands may be within a spectrum of wavelengths between about 500 nm to about 900 nm. In another example, the one or more passbands may be discrete narrow passbands within a spectrum of wavelengths between about 500 nm to about 900 nm. In another example, radiation source 402 generates light within the ultraviolet (UV) spectrum of wavelengths between about 225 nm and 400 nm. Radiation source 402 may be further configured to provide one or more passbands having substantially constant center wavelength (CWL) values over a long period of time (e.g., over a lifetime of radiation source 402). Such configuration of radiation source 402 may help to prevent the shift of the actual CWL values from the desired CWL values, as discussed above, in current metrology systems. And, as a result, the use of constant CWL values may improve long-term stability and accuracy of metrology systems (e.g., metrology system 400) compared to the current metrology systems.

Projection grating 404 may be configured to receive the beam (or beams) of radiation generated from radiation source 402, and provide a projected image onto a surface of a substrate 408. Imaging optics 406 may be included between projection grating 404 and substrate 408, and may include one or more lenses, mirrors, gratings, etc. In some embodiments, imaging optics 406 is configured to focus the image projected from projection grating 404 onto the surface of substrate 408.

In some embodiments, projection grating 404 provides an image on the surface of substrate 408 at an angle θ relative to the surface normal. The image is reflected by the substrate surface and is re-imaged on detection grating 412. Detection grating 412 may be identical to projection grating 404. Imaging optics 410 may be included between substrate 408 and substrate detection grating 412, and may include one or more lenses, mirrors, gratings, etc. In some embodiments, imaging optics 410 is configured to focus the image reflected from the surface of substrate 408 onto detection grating 412. Due to the oblique incidence, a height variation (Z_{w}) in the surface of substrate 408 will shift the image projected by projection grating 404 when it is received by detection grating 412 over a distance (s) as given by the following equation (1):

s=2Z_{w} sin(θ) (1)

In some embodiments, the shifted image of projection grating 404 is partially transmitted by detection grating 412 and the transmitted intensity, which is a periodic function of the image shift. This shifted image is received and measured by detector 414. Detector 414 may include a photodiode or photodiode array. Other examples of detector 414 include a CCD array. In some embodiments, detector 414 may be designed to measure wafer height variations as low as 1 nm based on the received image.

Exemplary Embodiments of Alignment of Scatterometer Based Particle Inspection System

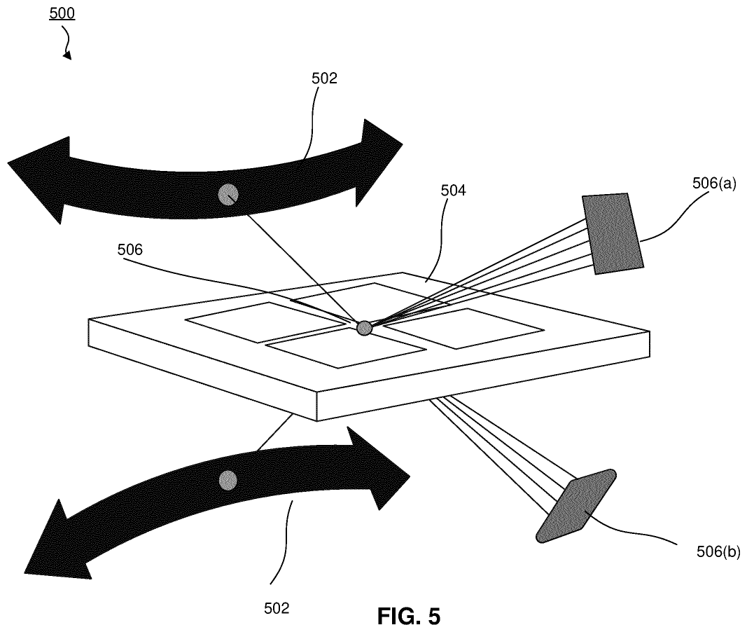

FIG. 5 shows a schematic of a lithographic patterning device inspection system 500 using laser scanning, according to some embodiments. In one example, inspection system 500 includes laser light source scanners that scan a surface of the lithographic patterning device in an X-direction 502 (across the lithographic patterning device) while the lithographic patterning device 504 slowly moves past the scanning laser. It can be appreciated that the scanning operation may be done on a glass side (e.g., 502(a) and/or a pellicle side (e.g., 502(b)). If there is contamination present on lithographic patterning device 504, then light may scatter and detector 506 may process the scattered light and provide further analysis of the detected contamination, as will be further described herein. It can be appreciated that detector 506 may be positioned at different locations to detect different scanning operations (e.g., position 506(a) to detect glass side scanning operations and/or position 506(b) to detect pellicle side scanning operations).

In some embodiments, if no contamination is detected, then the detector may not detect any scatter from the surface of lithographic patterning device 504, and the detected light would not be further processed. As noted earlier, any contamination found on a surface of lithographic patterning device 504 may result in a modification of the processed pattern that would yield an unintended pattern or a malfunctioning circuit.

In one example, detector 506(a) may detect the intensity of the light to determine a size of particle 508 by detecting the reflected intensity level. This may be done in a manner that correlates higher levels of intensity with bigger particle size. This is because bigger particles will scatter more light, and accordingly, will appear brighter to detector 506(a), wherein smaller particles will scatter less light, and accordingly, will appear dimmer to detector 506(a).

It can be appreciated that the size-intensity correlation is but one measure to determine the size of particle 508. In some examples, particle 508 may be a small but highly reflective particle (e.g. metallic) and thus, the intensity correlation may yield a particle size that appears larger than it is in reality. Alternatively, particle 508 may be a large low-reflective particle (e.g. carbon), and thus, the intensity correlation may yield a particle size that appears smaller than it is in reality.

Accordingly, further processing may provide improved detection of a particle and particle size contaminating a surface of a lithographic patterning device, as will be further described herein.

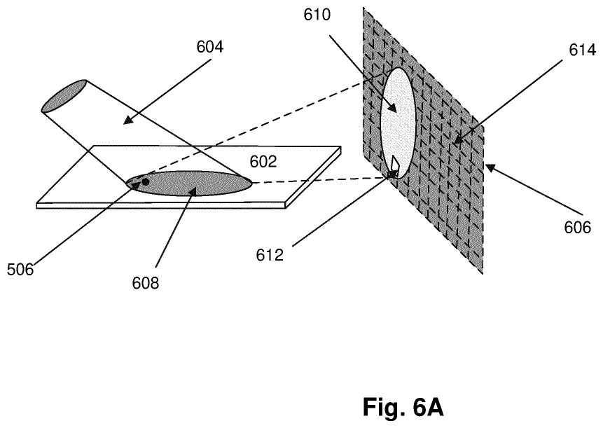

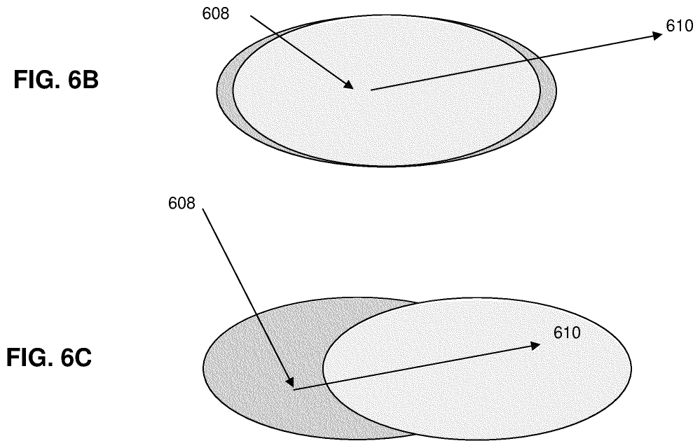

In one example, as further described in FIGS. 6A-6C, alignment may be an important factor in detection of a particle image at the detector plane. Looking at FIG. 6A for example, FIG. 6A describes a lithographic patterning device 602 (e.g. reticle) that is subjected to an illumination beam 604. Particle detection may be accomplished by scatterometry where an illumination spot is raster scanned across a substrate. As previously noted, when there is a particle on the substrate (e.g. surface of a reticle/lithographic patterning device 602), the scattered light may be measured by a static photodetector 606. It can be appreciated that the in some embodiments the photodetector is also movable. The movement of the photodetector may follow a raster scan or other scan order that would enable the scanning of the entire surface of the lithographic patterning device. In one example, the intensity of the detected light may be related to the size of the detected particle.

To measure micro level particles, the optics may be positioned to sub-micron tolerances. This requires a level of alignment between an illuminated area 608 on a reticle and a detected area 610 on detector 606. As such, mechanical tolerances and optical distortions may present dynamic alignment errors which may be difficult to correct. For example, the illumination spot must be precisely aligned such that when it hits a particle 506, the scattered light is positioned into the photodetector 606. It is worth noting that if the lithographic patterning device 602 is completely clean, reflected light may be dark, and light may go into a beam dump. When there is any type of contamination, however, that the irradiated contaminant may create light scatter that may need to be measured by a photodetector 606. Accordingly, a high degree of alignment of the light spot (from the scatter) and the photodetector may be required and would need to be on the order of microns which, as previously noted, requires specialized manufacturing tools.

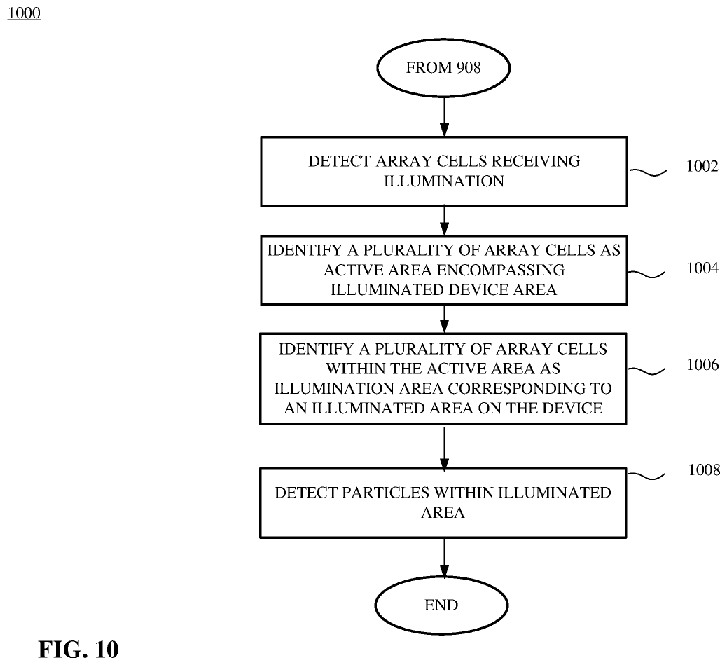

In some embodiments, as illustrated in FIGS. 6B and 6C, when there is a substantial overlap between an illuminated spot 608 and a detected spot 610, a photodetector's ability to accurately detect particle contamination may be diminished. For example, in FIG. 6B, the detector may still detect contamination in the overlapped area but may not do so in the fringe areas that are not overlapped. Moreover, when the overlap is not well aligned (e.g., FIG. 6C), an illuminated pixel that may contain the particle may not be aligned with a detection pixel because it is not within the overlapped/aligned area. As such, a detector may not be able to detect the particle because the detector may not process any information related to a pixel from which scattered light may be received. As will be further described in FIG. 10, particle images 612 detected within area 610 may be determined to be signals that are processed by the detector, wherein any detection or signal generated by pixels that are not within area 610 (e.g., from pixels 614) may be deemed as a false positive detection and discarded.

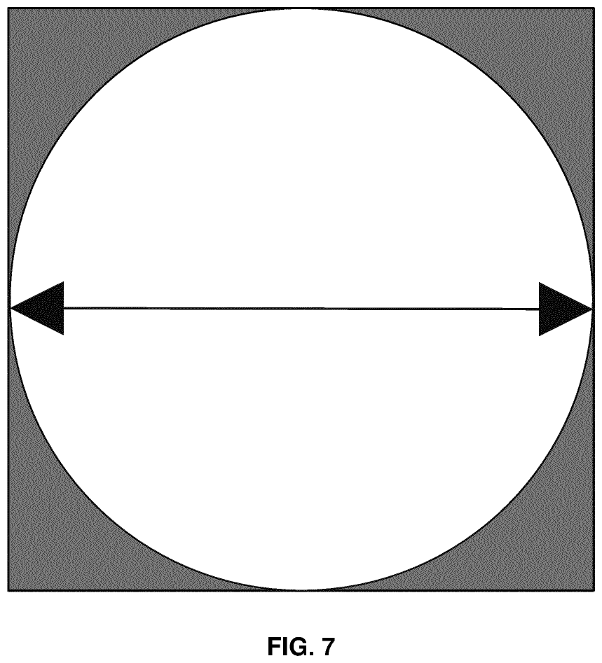

FIG. 7 illustrates a traditional spot across photodetector that requires perfect alignment, according to some embodiments. For example, a traditional spot across a photodetector may be required for perfect alignment between the illuminated area and the detected area.

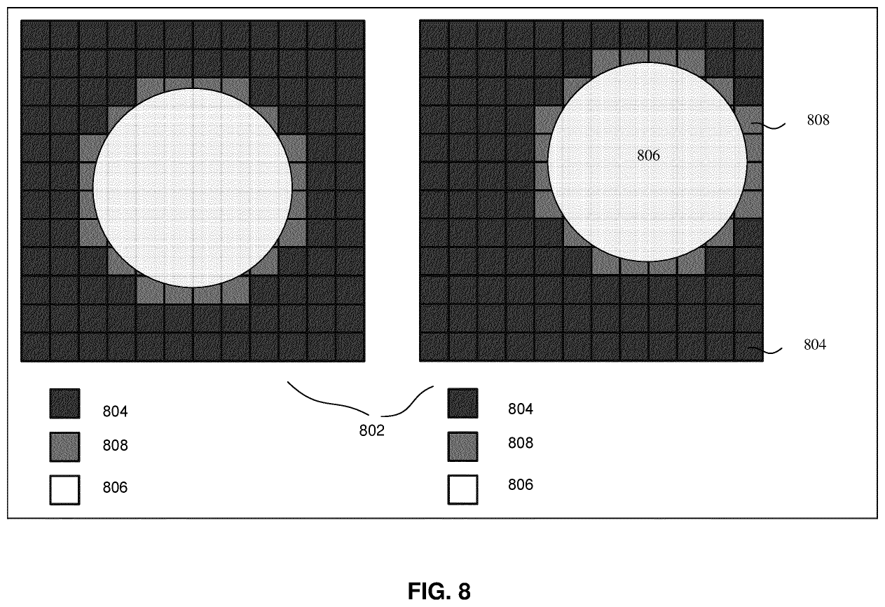

To overcome the stringent alignment requirement between illuminated area and detector area, the present disclosure may implement a two dimensional image sensor array, as illustrated in FIG. 8, to improve positioning tolerances of the illumination spot, according to some embodiments.

In FIG. 8, a sensor array that is larger than the intended reflected spot may be utilized. This improves the optical alignment tolerances and improves manufacturability. In one embodiment, a two dimensional image sensor array in the form of a charge coupled device (CCD), a complementary metal-oxide semiconductor (CMOS), or discrete photodetectors in place of a single photodiode cell may be used. In another embodiment, the array may be an array of photodiodes.

The use of a photodetector array, such as a photodiode array, may allow for positioning tolerances of the illumination spot, a polygon mirror, optics or photodetector to all be relaxed since the image sensor array is oversized and the resulting spot may fall on different area of the image sensor array without precise alignment required. For example, area 802 may represent the entire area of photodetector array, which may capture unwanted reflections 804, and illumination spot 806 within a predefined active pixel area 808. Illumination spot 806 can be detected at any position within area 802 (e.g., side, corner, middle, etc.). In one embodiment, active pixel area 808 may be identified/defined based on a calibration process as defined in FIG. 10 for example. Such calibration allows for an inspection system to have increased tolerance and flexibility in the alignment or correspondence between an illuminated area on a lithographic patterning device and illuminated area on a detector, while maintaining high detection accuracy because the detector array is big enough to achieve complete overlap.

In one embodiment, an image processing algorithm may be devised and calibrated to select which pixels to make active and which pixels to ignore as these contain unwanted noise due to light not originating from the particle. Using this algorithm, any alignment drift over time would not create a problem as that incurred when a single photodiode is used because the array enables the accommodation of higher tolerances within the oversized detection area. Moreover, pellicle sag sometimes may cause an illumination spot to vary. Accordingly, this also can be calibrated out by dynamically activating different pixels as the spot traverses across the lithographic patterning device. According to one aspect, a calibration reticle with a known particle size may be placed into the particle scanner system.

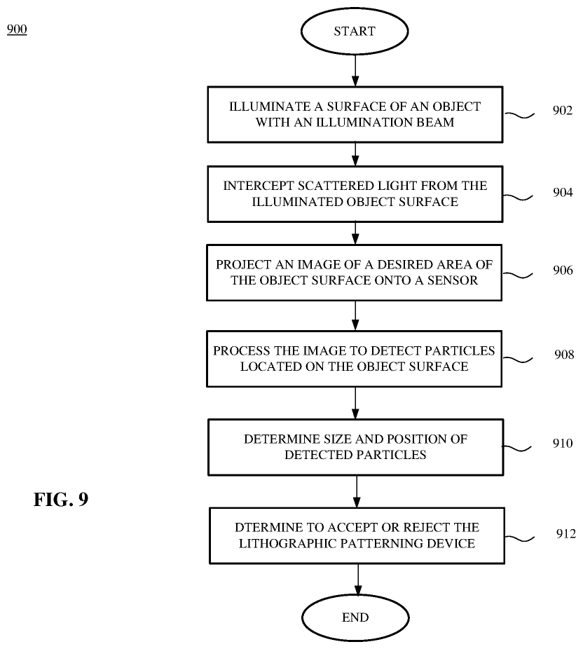

Based on the alignment of optics and photodetector, the particle may scatter light into a specific area of the photodetector array. According, the calibration processing algorithm may detect which areas of the array are detecting light and which are not. As such, areas that are receiving light may be turned on for future particle scans, while areas that do not receive light during the calibration process will be turned off for future particle scans. Moreover, pixel areas that receive particle light may be subject to threshold processing to determine if a signal from that specific pixel area should be used or discarded. A further description of the calibration and readout methods is provided herein with reference to FIGS. 9-11.

FIG. 9 illustrates a flow diagram illustrating an example method 900 for inspecting a surface of an object, such as a reticle or pellicle (e.g., lithographic patterning device) according to some embodiments. It is to be appreciated that the operations of the method need not be performed in the order shown and some operations may be optional or added.

Method 900 begins at step 902. In step 902, a surface of an object (e.g., a reticle, a pellicle, etc.) is illuminated with an illumination beam. In an embodiment, the illumination beam is provided to the object surface at an oblique angle. In step 904, scattered light from the illuminated object surface is intercepted. In step 906, the scattered light is projected onto a sensor (e.g., sensor 504 of FIG. 5 including a sensor array). In an embodiment, the sensor “looks” at the object surface at an oblique angle, while the illumination beam can provide normal light. In step 908, the scattered light is processed to detect particles located on the object surface. For example, a processor coupled to the sensor can be used to analyze the real image for particle detection.

In step 910, particle sizes and positions of detected particles are determined. This information can be used to make decisions regarding use of the object being assessed. For example, a decision may need to be made 912 whether the object needs to be rejected based on whether the determined particle sizes and positions are within predetermined ranges or other limits.

FIG. 10 illustrates a flow diagram illustrating an example method 1000 for calibrating an inspection detector to inspect a surface of an object, according to some embodiments. It is to be appreciated that the operations of the method need not be performed in the order shown and some operations may be optional or added.

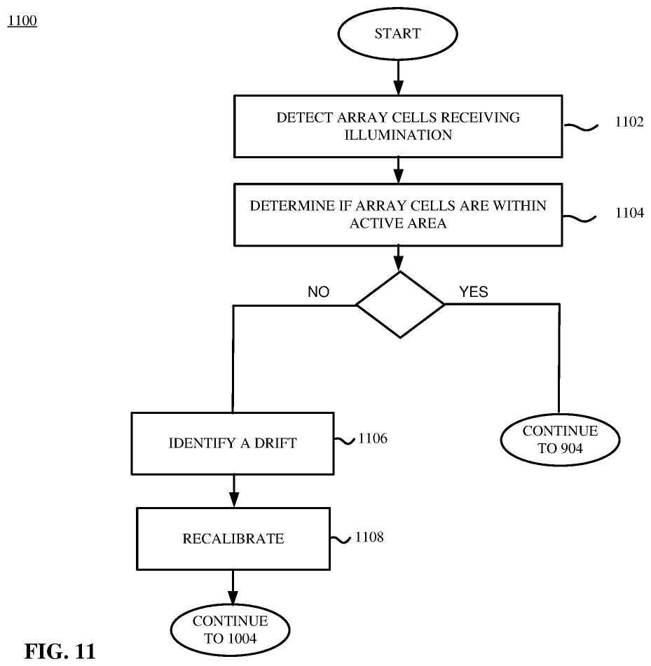

Method 1000 begins at step 1002, which may be a continuation of step 908. This method may be utilized to perform calibration to identify an area within the sensor array that will detect the scattered light. Additionally, this method may be utilized to recalibrate a detected drift operation, as will be further discussed in FIG. 11. At step 1002, cells are detected that receive the illumination. As previously described, this eliminates the need for a strict alignment tolerance in order to have as close to a perfect overlap between the illuminated area and the detected area as possible. Rather, the oversized sensor array can contain the entire region formed by the scatter light within a greater tolerance range.

At step 1004, a plurality of array cells are identified as being part of an active area (e.g., active area 808) encompassing the illuminated device area. At step 1006, a plurality of array cells, within the active area, are identified as illumination area (e.g., illumination area 806) corresponding to an illuminated area on the device. As described in FIG. 8, the active area is larger than the illuminated area and includes additional pixels.

The setting of both, an active area and a smaller illumination area allows for further relaxed tolerances. For example, some illuminated spots may encompass parts of a pixel, but not the entire pixel. Accordingly, including that pixel as an active pixel would allow the detector to read out an output of that pixel to cover the entirety of the illuminated spot. Otherwise, that portion of the pixel will not be read out, resulting in portions of the illumination spot not being read out. When the illumination area is identified, particles within the illuminated area may be detected at step 1008. In this regard, the detector may determine that the signal received from pixels within the illuminated area as a signal being received from pixels classified as active pixels, and may further determine a signal corresponding to a presence of a foreign particle (e.g., particle) in response to the detection signal being received from those pixels classified as active pixels.

When detector cells receive scattered light, they generate a signal (e.g., a detection signal based on the received radiation). The detector may then generate an overall detection signal that is a sum of one or more pixel outputs of the detector. Based on the detection signal, the detector may identify a spurious signal and a signal corresponding to a presence of a foreign particle on the surface of a lithographic patterning device (e.g., patterning device 606). In one example, this determination may be based on which pixel is generating the read out. For example, a spurious signal may be a signal generated at a pixel that has previously been identified as an inactive pixel (e.g. during calibration), wherein a signal corresponding to a presence of a foreign particle on the surface may be generated at a pixel that has previously been identified as active (e.g. within an active area designated as receiving the scattered light). When a signal is determined as a spurious signal, the signal may be classified as a false positive signal and discarded. The identification of false positive signals may help eliminate false detections and erroneous readouts that lead to process delays in a lithographic patterning apparatus.

FIG. 11 illustrates a flow diagram illustrating an example method 1100 for detecting an alignment drift, according to some embodiments. It is to be appreciated that the operations of the method need not be performed in the order shown and some operations may be optional or added.

At step 1102, within the detector array, a plurality of cells receiving illumination are detected. At step 1104, a determination is made if the array cells are within the previously defined active area, or outside. If the detected cells are within the active area, then the method continues to step 904 as previously discussed. If the any cell of the plurality of cells is determined to be outside the active area, at step 1106, a drift is determined and a recalibration 1108 is performed according to the method provided in FIG. 10.

A lithographic apparatus (e.g., lithographic apparatus 100) applies a desired pattern onto a substrate, such as onto a target portion of the substrate. During manufacture of integrated circuits (ICs) with a lithographic apparatus, a lithographic patterning device (e.g., a mask or a reticle) generates a circuit pattern to be formed on an individual layer in an IC. This pattern may be transferred onto the target portion (e.g., comprising part of, one, or several dies) on the substrate (e.g., a silicon substrate). To reduce manufacturing cost of ICs, it may be beneficial to expose multiple substrates of each IC. Likewise, the lithographic apparatus may be in constant use. That is, in some embodiments in order to keep manufacturing cost of all types of ICs at a potential minimum, the idle time between substrate exposures is also minimized. This can include inspection, particle detection and calibration. Thus, the lithographic apparatus can absorb heat which can cause expansion of the apparatus's components leading to drift, movement, and uniformity changes.

In order to ensure good imaging quality on the patterning device and the substrate, a controlled uniformity of the illumination beam may be maintained. As such, the entire lithographic process that the illumination beam may be controlled with at least some uniformity. Therefore, compensation for any expansion that causes a drift, or a movement, may need to be performed using recalibration. In some examples, a photodetector array may be oversized in relation to the illuminated region on the lithographic patterning device, physical recalibration by any type of movement or physical adjustment of the detector may not be not necessary. Rather, the recalibration process may re-define the active and illumination regions based on the detected scattered light projected onto the sensor array.

Moreover, the drift detection may be part of a wider diagnostic capability. In this regard, a centroid tracking algorithm may be utilized to predict when alignment is close to maximum out of spec setting with regard to not only drift, but movement and any types of uniformity changes. According to an embodiment, when a calibration reticle with known particle sizes is inserted into the system for calibration, the active pixels signal intensity may be measured and a centroid can be calculated. For example, if the signal is evenly split between the two pixels, the centroid is in the center of the two pixels. As one pixel starts to record a stronger intensity value, and the other pixel starts to become lower intensity, the “centroid” may be seen as moving towards the higher intensity pixel. This centroid may be detected with two or more pixels. Accordingly, over a period of time, the centroid may be tracked and drift data may be measured. This can help determine if the system is moving towards an out of tolerance condition. An out of tolerance condition may be one in which the active pixels are no longer tracking the particle with the right active pixels.

While the inactive photodiodes may be set to reject unwanted light, there is a benefit to measure the output of the inactive photodiodes to measure an intensity of false positives due to unwanted scatter light. According to some embodiments, a real particle may illuminate within the calibrated detection area. A ghost particle may illuminate the detection area as well as the surrounding area. Accordingly, by monitoring the signal intensity of the surrounding areas, it is possible to flag a detection of a ghost particle, i.e. a false positive detection.

A sensor array may be an array of photodiodes, a CCD array or the like. An array of photodiodes can provide additional advantages to that of a CCD array for example. For example, the photodiode's processing times may increase the processing speeds of image readouts and detections.

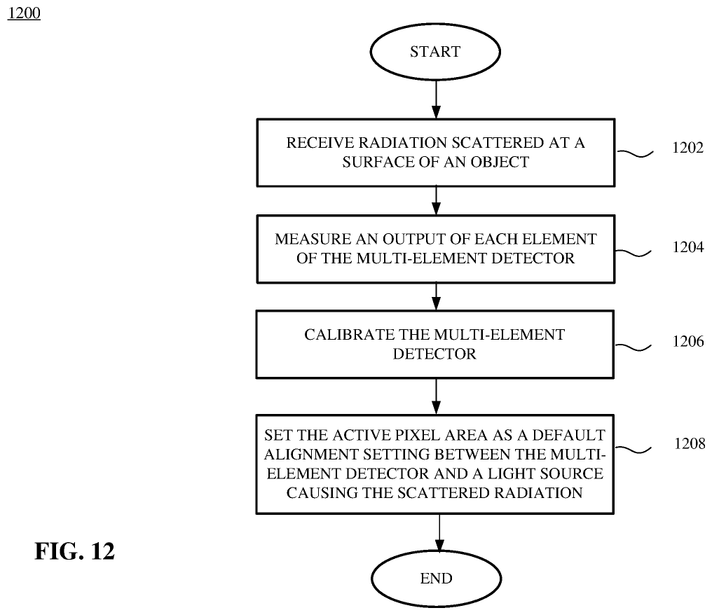

FIG. 12 illustrates a flow diagram illustrating an example method 1200 for aligning illumination optics with detection optics, according to some embodiments. According to some aspects, method 1200 may include the operation of receiving 1202, at a multi-element detector within the inspection system, radiation scattered at a surface of a lithographic patterning device. An illumination source may illumination a portion of a lithographic patterning device (e.g., reticle). As noted previously, alignment between illumination source and a detection system may be required to improve detection accuracy. In this regard, and to improve alignment tolerances, a multi-element detector may be used. Such detector may be a photodiode array. While other multi-element detectors may be used (e.g., CCD, CMOS, etc.), a photodiode array sensor provides certain advantages including efficient and expedient processing of illuminated area and related data.

Method 1200 may also include a measuring operation 1204 of an output of each element of the multi-element detector, the output corresponding to the received scattered radiation. In this regard, the detector may measure an output of each photodiode of the photodiode array to determine where the scattered light is incident on the photodiode array. This can eliminate the need for manual physical alignment between an illumination source and a detector that may need to be constantly adjusted. Instead, method 1200 allows for an increased detection area that can programmatically enable or disable the pixels designated within an active area that receives the light. In this regard, when there is a system drift, or misalignment over time, a simple recalibration process can take place as opposed to an operation of manually recalibrating an alignment. This also allows for greater manufacturing tolerances of the optical system because any misalignment can be compensated for or adjusted for by controlling which pixels to activate/deactivate. Accordingly, pixels that receive scattered light will have an output and pixels that do not receive light may not have an output, or may have an output that is below a threshold of sufficient amplitude value.

Method 1200 may further include a calibration operation 1206. In this regard, method 1200 may including calibrating the multi-element detector by identifying an active pixel area comprising one or more elements of the multi-element detector with a measured output being above a predetermined threshold, and identifying an inactive pixel area comprising a remainder of elements of the multi-element detector. As described herein FIG. 8, when an illumination spot is incident onto photodiode array, pixels that receive the light may be designed as active pixels and pixels that do not receive the light or receive unwanted reflections may be designated as inactive pixels. This designation may depend on a measured value output for each pixel. As noted herein, pixels receiving light may provide an output above a predetermined threshold, e.g., an output with an amplitude sufficient to correspond to the received incident light.

Method 1200 may further include setting 1208 the active pixel area as a default alignment setting between the multi-element detector and a light source causing the scattered radiation. Setting an active pixel area is important to align the light incident on a reticle with its corresponding reflection (scatter) on a detector. Once the active area is determined, the active area may be designated as the location from which all future readings may be taken (unless a drift condition occurs). At this point, it can be said that the detector is calibrated and ready to perform inspection operations.

Method 1200 may include other operations not illustrated in FIG. 12. For example, method 1200 may including receiving a second radiation scattered at the surface of the object and generating a detection signal based on outputs of the active pixels. In this regard, the second radiation scatter may be one that occurs after the detector is calibrated. Moreover, the detection signal may be a signal indicative of whether a particle is detected or not. As noted here, a reticle with no contamination may not produce scattered light when illuminated. Accordingly, when light is received at the detector, the detector may measure the output of each pixel within the active area and perform a weighted sum operation (using an operational amplifier or the like). The multi-element detector may then generate a detection signal indicative of whether a contaminant is present. For example, if a contaminant is present, then a weighted sum may be equivalent to a value “1” wherein a weighted sum may be equivalent to “0” or a close value. This indicates whether a contaminant is present or not.

According to some embodiments, additional measures may be taken to determine a location of the contaminant. For example, additional processing may be performed by the detector to determine which pixel(s) within the active pixel area have the largest output (indicating strongest intensity). Since the illumination spot on the detector corresponds to an illumination spot on the reticle, then a detected location of a contaminant, as measured by the pixel outputs, would correspond to the location within the illumination spot on the reticle. Accordingly, this operation may extrapolate the location of the contaminant from the determining where it is located within the active pixel area.

Method 1200 may also enable the detector to discard outputs of an inactive pixel area. This inactive pixel area is an area outside the designated active pixel area. Alternatively, the detector may also read outputs of pixels within the inactive pixel area to determine whether a false positive condition occurs. Such condition may be defined where a system receives stray light.

An illumination spot generated by the scattered radiation on the surface area of the detector may be smaller than a detection surface area of the detector where the active pixel area comprises the illumination spot. This may be because the illumination spot may be circular and the active pixel area may not necessarily be so.

In some aspects of the disclosure, misalignment conditions may occur due to drift condition, or pellicle sag, which may cause the illumination spot to vary. Accordingly, in one example, method 1200 may include calibrating out variation in the illumination spot by dynamically activating different pixels as the spot traverses across a reticle. Accordingly, method 1200 may require a new calibration process whereby a new set of photodiodes are detected and determined to be part of the active area. This may enable the detector to adjust the active pixel area to accommodate changes in the tolerances and/or any of the above-noted conditions.

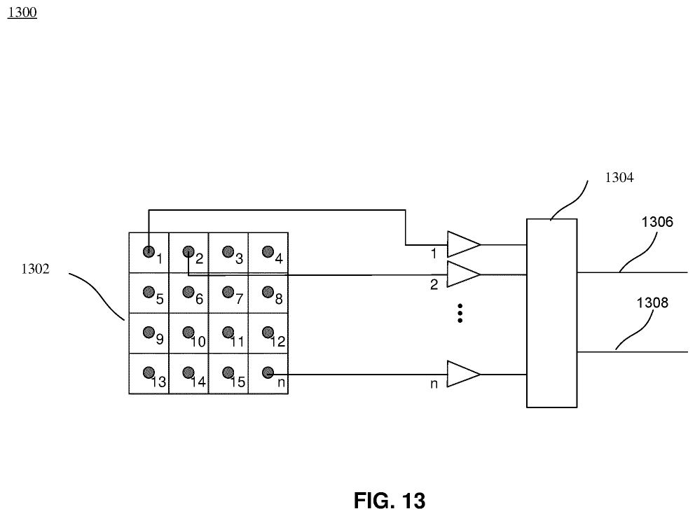

FIG. 13 illustrates a detector device 1300 including an array of photodiodes, according to some embodiments. A photodiode array (PDA) 1302 can be a linear array of discrete photodiodes on an integrated circuit (IC) chip. In one example, the PDA may be placed at the image plane of a spectrometer to allow a range of wavelengths to be detected simultaneously. In this regard it can be thought of as an electronic version of a photographic film. According to some embodiments, processor 1304 may process signals received from the PDA and determine if the received signal is a signal indicative of a detected particle (i.e., detected signal 1306), or is a signal indicative of a ghost particle (i.e., ghost signal 1308 indicating a false positive). In one aspect, signals from pixels identified during the calibration process as being active pixels are summed up and processed. For example, a calibration process may identify pixels 6, 7, 10 and 11 as active pixels (it may be understood that this is but one example, and any number of pixels may be identified during the calibration process as active pixels, and may range from 1 pixel to n pixels), a collective output of these signals may be summed and processed as a signal indicative of a particle detected on a surface of a lithographic patterning device.

As previously described, PDA 1302 may also detect a ghost signal 1308. In one aspect, PDA 1302 may be configured to reject data received from pixels that are not identified as active. For example, using the above example, the processor may be configured to only process data received from pixels 6, 7, 10, and 11, and nullify or delete data received from any other pixel within PDA 1302. In another aspect, processor 1304 may be configured to process signals received from non-active pixels (e.g., pixels 1, 2, 3, 4, etc.). In this regard, processor 1304 may process all signals received from non-active pixels and output a detected ghost signal 1308 indicative of a ghost particle (false positive) detection.

As previously described, calibration procedure can determine which of the photodetectors to make active. In this regard, outputs of those active photodetectors are summed together to produce an output signal. Inactive photodiodes may be classified as such, and may be configured to reject unwanted light that causes false positive readings.

In one embodiment, the processor may be an analog summing processor or a digital summing processor. In analog summing, each analog output can be enabled or disabled before going to a summing amplifier. In the digital summing, each output can be discretely digitized and enabled/disabled digitally.

In some embodiment, manufacturing of particle inspection systems may allow for detect particle contamination, and recalibrating to compensate for drift and other component variabilities; providing relaxed optical alignment tolerances between illumination system and photodetector; providing a relaxed drift budget over time due to the ability to compensate by recalibration; and provide adequate throughput that can meet a requisite throughput because the use of a photodiode array which can be sampled simultaneously suing discrete analog-digital converters running at the same sample rate as the reticle inspection system.

To determine a size of a detected particle an intensity of the scattered light may be measured. As previously noted, larger objects may scatter more light, and thus, provide a higher intensity reading at the detector. However, that is not always the case, since some objects may have high reflectivity properties, and thus, may provide higher intensity than larger objects, simply because of their composition, rather than size. Accordingly, a use of an imaging device may be further utilized, in addition to the photodetector array, to more accurately measure a size of the detected object.

In one example, a high resolution 2D pixel array (i.e. camera) may be utilized to determine the size by zooming in enough to directly measure the number of pixels. The pixels may be made small enough to have enough resolution to see the smallest particle size of interest. To use a 2D sensor in scatterometry mode for coarse detection, all pixels would need to be read out at a rate of millions of frames per second. This speed is not feasible of any sensor. Moreover, the use of yet another sensor may face space constraints.

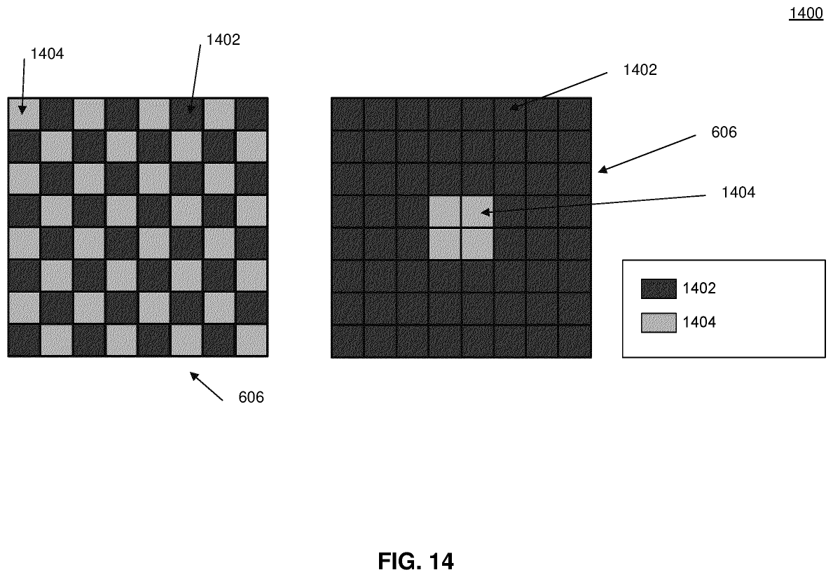

FIG. 14 shows a sensor array 1400 including a detector (e.g. detector 606 with detector pixels) arranged in different configurations according to some embodiment. In some embodiment, detector 606 incorporates two sensor technologies in a singular physical sensor to read out in both scatterometry mode and high resolution imaging mode. According to some aspects, detector 606 may be configured to incorporate two or more sensor technologies: CCD/CMOS pixels 1402 and photodiode(s) 1404 in a 2D array. The configurations or placement of the photodiodes can be arranged in any arrangement, two of which, are shown in FIG. 14. The dedicated photodiodes are electronically summed together giving an instantaneous value equivalent to the total photons on all the photodetector pixels. This method allows for high speed readout since photodiodes can be read out millions of time per second, while CMOS/CCD pixels must be clocked out serially and generally have frame rates up to a few thousand frames per second.

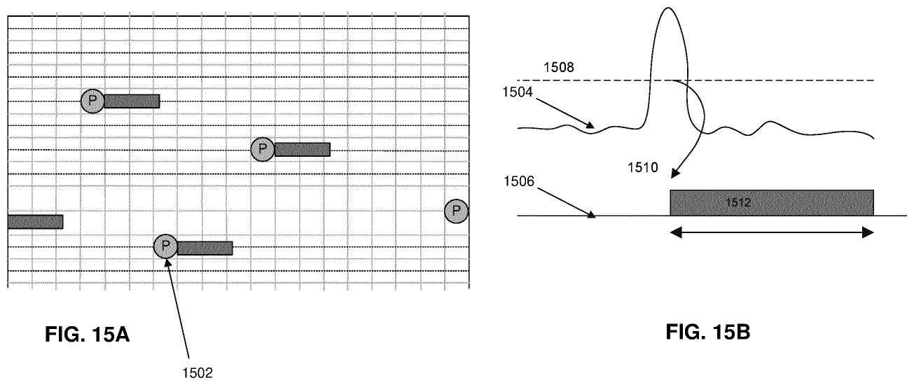

FIGS. 15A-15B illustrate a combination of detectors used to detect particles on a lithographic patterning device, according to some embodiments. In FIGS. 15A-15B, the sensor may be used to coarsely detect particles and provide readouts at every pixel 1502. Accordingly, once a particle is discovered with high resolution slower (CCD/CMOS), pixel data can be read out. To avoid re-triggering on the same particle (for example in the next line scan), a keep out area the size of the image sensor would be kept to avoid duplicating the triggering event. In this regard, the photodiode readout signal 1504 may be read out initially. When a value of the readout signal 1504 exceeds a threshold 1508, it is determined that a particle of some type is detected, and this triggers a CMOS readout operation to take place (e.g., CMOS readout signal 1506). In this manner, the two detectors can operate in tandem where the photodiode array detects the particle and CCD/CMOS array can detect the size of the detected particle. Moreover, in one example, a block out zone may be triggered 1510 when the 2D array readout 1512, of the CCD/CMOS array is activated in order to avoid the triggering of another particle by the photodiode array. It can be appreciated that during the 2D array readout 1512, another exposure cannot be triggered. It would be possible, however, to perform a rescan operation if two particles are very close to each other. Accordingly, the block out zone may temporarily put a hold on photodiode array readouts until CCD/CMOS readout is completed.

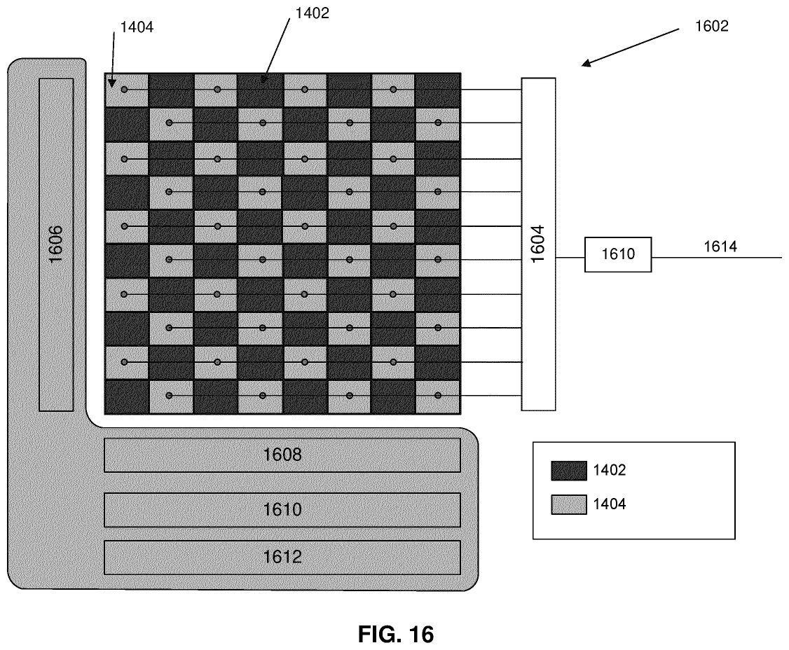

According to some embodiments, a detector array may comprise one or more types of pixel technologies that enable the detector to process data and identify particles and particle sizes in a more efficient and expedient manner. In some embodiments, as illustrated in FIG. 16, detector 1602 may include a combination of CMOS/CCD pixel array 1402 and a photodiode pixel array 1404. This combination may allow one array to detect the particle (e.g., photodiode array 1404) while the other array to detect particle size (e.g., CMOS/CCD array 1402). This is because a photodiode array may process data faster as it does not require high resolution capture/processing of information. Thus, photodiode array may quickly identify whether a particle exists or not, and then CMOS/CCD pixel processing can follow with detection of a particle size. According to one aspect, the photodiode array 1404 may determine that a series of pixels identified a particle (in accordance with example of FIG. 13). Accordingly, a processor (e.g., processor 1304) may request summing amplifier 1604 to process pixel data from CMOS/CCD pixels within a vicinity of photodiode active pixels. In one aspect, the processor may include circuitry including a row decoder 1606 and a column decoder 1608, an analog to digital converter 1610 and an interface 1612. According to some embodiments, analog to digital converter 1610 may output a pixel value 1614 indicative of the pixel reading for the particle detection. In one example, the pixel value 1614 may correspond to a single pixel value.

According to some embodiments, the approach described in FIG. 16 provides a two-step solution that 1) increases efficiency of particle detection by quickly detecting particles, and 2) increases efficiency of particle size detection by collecting image data surrounding the active pixels that detected the particle.

Other aspects of the invention are set out in the following numbered clauses.

1. An inspection method comprising:
receiving, at a multi-element detector within an inspection system, radiation scattered at a surface of an object;
measuring, with processing circuitry, an output of each element of the multi-element detector, the output corresponding to the received scattered radiation;
calibrating, with the processing circuitry, the multi-element detector by identifying an active pixel area comprising one or more elements of the multi-element detector with a measured output being above a predetermined threshold, and identifying an inactive pixel area comprising a remainder of elements of the multi-element detector; and
setting the active pixel area as a default alignment setting between the multi-element detector and a light source causing the scattered radiation.
   2. The inspection method of clause 1, further comprising:
receiving, at the multi-element detector, second radiation scattered at the surface of the object; and
generating a detection signal based on outputs of the active pixels, the detection signal indicating a presence of a foreign particle on the surface.
   3. The inspection method of clause 2, further comprising
determining, based on an output of the inactive pixel area, a spurious signal, the spurious signal indicating scatter light; and
discarding the output of the inactive pixel area.
   4. The inspection method of clause 1, wherein
an illumination spot generated by the scattered radiation on the surface area of the multi-element detector is smaller than a detection surface area of the multi-element detector, and
the active pixel area comprises to the illumination spot.
   5. The inspection method of clause 1, further comprising:
determining a spurious signal in response to the detection signal being received from the inactive pixel area; and
classifying the spurious signal as a false positive signal.
   6. The inspection method of clause 2, further comprising:
determining a location of the foreign particle based on
measuring pixel outputs from pixels within the active pixel area,
identifying one or more pixels within the active pixel area with the highest output levels, and
extrapolating a location of the foreign particle based on a location of the identified one or more pixels within the active pixel area.
   7. The inspection method of clause 2, further comprising performing a compensation operation, the compensation operation comprising:
identifying a misalignment condition between the multi-element detector and the light source; and
reinitializing the calibration operation in response to identifying the misalignment.
   8. The inspection method of clause 7, the identifying further comprising:
detecting a new plurality of elements within the active pixel area or within the inactive pixel area bordering the active pixel area that are outside of an illumination spot generated by the scattered radiation on the surface area of the multi-element detector, the new plurality of elements each generating an output above a predetermined threshold over one or more inspection operations.
   9. The inspection method of clause 7, further comprising:
setting a new active pixel area as a default alignment setting between the multi-element detector and the light source.
   10. The inspection method of clause 7, wherein the misalignment condition is a drift condition.
   11. A lithographic inspection apparatus comprising:
a multi-element detector configured to
measure, with processing circuitry, an output of each element of the multi-element detector, the output corresponding to the received scattered radiation,
calibrate, with the processing circuitry, the multi-element detector by identifying an active pixel area comprising one or more elements of the multi-element detector with measured outputs being above a predetermined threshold, and identifying an inactive pixel area comprising a remainder of elements of the multi-element detector, and
set the active pixel area as a default alignment setting between the multi-element detector and a light source causing the scattered radiation.
   12. The lithographic inspection apparatus of clause 11, wherein the detector is further configured to:
receive second radiation scattered at the surface of the object, and
generate a detection signal based on outputs of the active pixels, the detection signal indicating a presence of a foreign particle on the surface.
   13. The lithographic inspection apparatus of clause 12, wherein the detector is further configured to:
determine, based on an output of the inactive pixel area, a spurious signal, the spurious signal indicating scatter light, and
discard the output of the inactive pixel area.
   14. The lithographic inspection apparatus of clause 11, wherein
an illumination spot generated by the scattered radiation on the surface area of the multi-element detector is smaller than a detection surface area of the multi-element detector, and
the active pixel area correspond to the illumination spot.
   15. The lithographic inspection apparatus of clause 11, wherein the detector is further configured to:
determine a spurious signal in response to the detection signal being received from a pixel outside the active pixel area, and
classify the spurious signal as a false positive signal.
   16. The lithographic inspection apparatus of clause 12, wherein the detector is further configured to:
determine a location of the foreign particle based on
measuring pixel outputs from pixels within the active pixel area,
identifying one or more pixels within the active pixel area with the highest output levels, and
extrapolating a location of the foreign particle based on a location of the identified one or more pixels within the active pixel area.
   17. The lithographic inspection apparatus of clause 12, wherein the detector is further configured to:
perform a compensation operation, the compensation operation comprising:
identifying a misalignment condition between the multi-element detector and the light source, and
reinitializing the calibration operation in response to identifying the misalignment.
   18. The lithographic inspection apparatus of clause 17, the identifying operation by the detector further comprising:
detecting a new plurality of elements within the active pixel area or bordering the active pixel area that are outside of an illumination spot generated by the scattered radiation on the surface area of the multi-element detector, the new plurality of elements each generating an output above a predetermined threshold.
   19. The lithographic inspection apparatus of clause 16, wherein the detector is further configured to:
setting a new active pixel area as a default alignment setting between the multi-element detector and the light source.
   20. The lithographic inspection apparatus of clause 16, wherein the misalignment condition is a drift condition.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the disclosure in the context of optical lithography, it will be appreciated that the disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

In the embodiments described herein, the terms “lens” and “lens element,” where the context allows, can refer to any one or combination of various types of optical components, including refractive, reflective, magnetic, electromagnetic, and electrostatic optical components.

Further, the terms “radiation,” “beam,” and “light” used herein may encompass all types of electromagnetic radiation, for example, ultraviolet (UV) radiation (for example, having a wavelength of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

The term “substrate” as used herein may describe a material onto which material layers are added. In some embodiments, the substrate itself can be patterned and materials added on top of it may also be patterned, or may remain without patterning.

Although specific reference can be made in this text to the use of the apparatus and/or system according to the disclosure in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “patterning device,” “reticle,” “wafer,” or “die” in this text should be considered as being replaced by the more general terms “mask,” “substrate,” and “target portion,” respectively.

While specific embodiments of the disclosure have been described above, it will be appreciated that the disclosure can be practiced otherwise than as described. The description is not intended to limit the disclosure.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the present disclosure should not be limited by any of the above-described exemplary embodiments, but should be defined only in accordance with the following claims and their equivalents.

1. An inspection method comprising:
receiving, at a multi-element detector within an inspection system, radiation scattered at a surface of an object;
measuring, with processing circuitry, an output of each element of the multi-element detector, the output corresponding to the received scattered radiation;
calibrating, with the processing circuitry, the multi-element detector by identifying an active pixel area comprising one or more elements of the multi-element detector with a measured output being above a predetermined threshold, and identifying an inactive pixel area comprising a remainder of elements of the multi-element detector; and
setting the active pixel area as a default alignment setting between the multi-element detector and a light source causing the scattered radiation.

2. The inspection method of claim 1, further comprising:
receiving, at the multi-element detector, second radiation scattered at the surface of the object; and
generating a detection signal based on outputs of the active pixels, the detection signal indicating a presence of a foreign particle on the surface.

3. The inspection method of claim 2, further comprising
determining, based on an output of the inactive pixel area, a spurious signal, the spurious signal indicating scatter light; and
discarding the output of the inactive pixel area.

4. The inspection method of claim 1, wherein
an illumination spot generated by the scattered radiation on the surface area of the multi-element detector is smaller than a detection surface area of the multi-element detector, and
the active pixel area comprises to the illumination spot.

5. The inspection method of claim 1, further comprising:
determining a spurious signal in response to the detection signal being received from the inactive pixel area; and
classifying the spurious signal as a false positive signal.

6. The inspection method of claim 2, further comprising:
determining a location of the foreign particle based on
measuring pixel outputs from pixels within the active pixel area,
identifying one or more pixels within the active pixel area with the highest output levels, and
extrapolating a location of the foreign particle based on a location of the identified one or more pixels within the active pixel area.

7. The inspection method of claim 2, further comprising performing a compensation operation, the compensation operation comprising:
identifying a misalignment condition between the multi-element detector and the light source; and
reinitializing the calibration operation in response to identifying the misalignment.

8. The inspection method of claim 7, the identifying further comprising:
detecting a new plurality of elements within the active pixel area or within the inactive pixel area bordering the active pixel area that are outside of an illumination spot generated by the scattered radiation on the surface area of the multi-element detector, the new plurality of elements each generating an output above a predetermined threshold over one or more inspection operations.

9. The inspection method of claim 7, further comprising:
setting a new active pixel area as a default alignment setting between the multi-element detector and the light source.

10. The inspection method of claim 7, wherein the misalignment condition is a drift condition.

11. A lithographic inspection apparatus comprising:
a multi-element detector configured to
measure, with processing circuitry, an output of each element of the multi-element detector, the output corresponding to the received scattered radiation,
calibrate, with the processing circuitry, the multi-element detector by identifying an active pixel area comprising one or more elements of the multi-element detector with measured outputs being above a predetermined threshold, and identifying an inactive pixel area comprising a remainder of elements of the multi-element detector, and
set the active pixel area as a default alignment setting between the multi-element detector and a light source causing the scattered radiation.

12. The lithographic inspection apparatus of claim 11, wherein the detector is further configured to:
receive second radiation scattered at the surface of the object, and
generate a detection signal based on outputs of the active pixels, the detection signal indicating a presence of a foreign particle on the surface.

13. The lithographic inspection apparatus of claim 12, wherein the detector is further configured to:
determine, based on an output of the inactive pixel area, a spurious signal, the spurious signal indicating scatter light, and
discard the output of the inactive pixel area.

14. The lithographic inspection apparatus of claim 11, wherein
an illumination spot generated by the scattered radiation on the surface area of the multi-element detector is smaller than a detection surface area of the multi-element detector, and
the active pixel area correspond to the illumination spot.

15. The lithographic inspection apparatus of claim 11, wherein the detector is further configured to:
determine a spurious signal in response to the detection signal being received from a pixel outside the active pixel area, and
classify the spurious signal as a false positive signal.

16. The lithographic inspection apparatus of claim 12, wherein the detector is further configured to:
determine a location of the foreign particle based on
measuring pixel outputs from pixels within the active pixel area,
identifying one or more pixels within the active pixel area with the highest output levels, and
extrapolating a location of the foreign particle based on a location of the identified one or more pixels within the active pixel area.

17. The lithographic inspection apparatus of claim 12, wherein the detector is further configured to:
perform a compensation operation, the compensation operation comprising:
identifying a misalignment condition between the multi-element detector and the light source, and
reinitializing the calibration operation in response to identifying the misalignment.

18. The lithographic inspection apparatus of claim 17, the identifying operation by the detector further comprising:
detecting a new plurality of elements within the active pixel area or bordering the active pixel area that are outside of an illumination spot generated by the scattered radiation on the surface area of the multi-element detector, the new plurality of elements each generating an output above a predetermined threshold.

19. The lithographic inspection apparatus of claim 16, wherein the detector is further configured to:
setting a new active pixel area as a default alignment setting between the multi-element detector and the light source.

20. The lithographic inspection apparatus of claim 16, wherein the misalignment condition is a drift condition.
